(19) United States
(12) Patent Application Publication
(10) Pub. No.: US 2013/0295834 A1
(43) Pub. Date: Nov. 7, 2013

(54) MULTI-CHASSIS CLIMATE REGULATOR PLENUM

(71) Applicants: Matthew Allen Faist, El Dorado Hills, CA (US); Eric C. Peterson, Woodinville, WA (US)

(72) Inventors: Matthew Allen Faist, El Dorado Hills, CA (US); Eric C. Peterson, Woodinville, WA (US)

(73) Assignee: Microsoft Corporation, Redmond, WA (US)

(21) Appl. No.: 13/465,164

(22) Filed: May 7, 2012

(51) Int. Cl. F24F 7/00; H05K 5/02

(52) U.S. Cl. 454/184

(57) ABSTRACT

Climate regulation within a chassis of an electronics enclosure (e.g., a workstation case or a server cabinet) may be achieved through an airflow regulated by at least one climate regulator devices (e.g., a variable-speed fan array) and a plenum configured to direct the airflow at the components of the enclosure. The enclosure may store a set of chassis, each having a dedicated plenum and climate regulator devices. However, this architecture may be less efficient than an architecture wherein adjacently mounted chassis may connect plenums (e.g., directly connecting an exhaust of one plenum with an inlet of the adjacent plenum) to unify the airflow directed through several chassis. Additionally, the chassis may feature a removable portion of the plenum wall that provides access to the plenum, and the climate regulator devices may be mounted on the removable portion, such that detachment enables withdrawal and servicing of the climate regulator devices.

### BACKGROUND

Within the field of computing, many scenarios involve an enclosure of a set of devices, such as a cabinet for one or more servers respectively comprising a set of electronic components (e.g., processors, memory components, and nonvolatile storage devices), where one or more climate regulators apply a climate regulating effect to the components through the generation and conditioning of an airflow. As one example, because excess heat may disrupt the accurate operation of the components and eventually cause thermal damage, the enclosure may comprise thermal climate regulators, such as a set of fans positioned and configured to draw air into the enclosure, push the air over the components, and expel heated air out of the enclosure as exhaust. The enclosure may also comprise a plenum that serves to guide the airflow from the airflow inlet, near the components, and out through an exhaust.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

While the inclusion of a plenum in an enclosure may promote a consistent and directed airflow to facilitate climate regulation, many such enclosures implement the plenum in a manner that presents some deficiencies. As a first example, an enclosure may comprise two or more chassis, each storing a set of devices, and each featuring a dedicated set of climate regulators and a dedicated plenum for the devices. However, a per-chassis plenum and climate regulator set may be less efficient than an enclosure that shares the plenum and climate regulators for multiple chassis. As a second example, the plenum and climate regulators are often built into portions of the chassis that are difficult to access; e.g., the plenum may present the inlet ad climate regulators at the bottom of the enclosure below all of the devices, and/or at the back of the unit and behind all of the devices. Accessing the plenum and climate regulators for maintenance and upgrades may therefore involve unloading or reaching past several devices from the enclosure, and possibly moving and/or tipping the enclosure.

Presented herein are architectures for enclosures featuring a plenum that may present some advantages over other architectures. As a first example, the plenum may be integrated with a chassis in such a manner that if a first chassis is mounted in an enclosure adjacent to a second chassis, the plena of the first chassis and second chassis may be connected to form a joint plenum that directs a single airflow over the components of both chassis. The climate regulators of respective chassis may also be applied in a unified manner to regulate the climate of the airflow in the unified plenum. Additionally, a surface of the plenum may comprise a detachable plenum portion that may be detached to provide access to the plenum. For example, the climate regulators may be mounted on the detachable plenum portion, such that a user may detach the portion to withdraw the climate regulators from the plenum for servicing. These and other advantages may be achievable through the design of the chassis and climate regulators according to the techniques presented herein.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIG. 1 is an illustration of an exemplary scenario featuring an enclosure of a chassis and a climate regulator device directing an airflow through the chassis via a plenum.

FIG. 2 is an illustration of an exemplary scenario featuring an enclosure of two chassis and climate regulator devices directing an airflow through the chassis via a plenum joined between the chassis in accordance with the techniques presented herein.

FIG. 3 is an illustration of another exemplary scenario featuring an enclosure of two chassis and climate regulator devices directing an airflow through the chassis via a plenum joined between the chassis in accordance with the techniques presented herein.

FIG. 4 is an illustration of an exemplary scenario featuring a detachable plenum portion of an exterior plenum surface of the chassis enabling access to a plenum and a set of climate regulator devices mounted on the detachable plenum portion.

FIG. 5 is an illustration of an exemplary scenario featuring control of a climate regulator device to regulate an airflow through a chassis using a chassis management component and an airflow meter to provide a climate regulation feedback mechanism.

FIG. 6 is an illustration of an exemplary computing environment wherein one or more of the provisions set forth herein may be implemented.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, structures and devices are shown in block diagram form in order to facilitate describing the claimed subject matter.

A. Introduction

Within the field of computing, many scenarios involve an enclosure storing one or more devices, such as an enclosure storing a computer comprising a mainboard, one or more processors, volatile and nonvolatile storage, and communications components such as network adapters, or a server cabinet storing components comprising one or more servers. In these scenarios, the air within the enclosure may vary in particular climate properties, such as the temperature, humidity, air pressure, and the reduction of particulate matter (e.g., dust and smoke) of the air within the enclosure. The devices within the enclosure may be sensitive to such properties of the climate; e.g., electronic components may function reliably only within a range of operating temperatures, and excess humidity may disrupt electrical propagation of circuits. Additionally, the operation of the devices may alter such properties, e.g., by generating heat or creating particulate contaminants through friction between moving components, and may exacerbate undesirable climate conditions within the enclosure. The consistent and reliable operation of the devices within the enclosure may therefore depend on regulating various properties of the climate within the enclosure.

In view of these considerations, the enclosure may include one or more climate regulating components that are configured to regulate various properties of the climate within the enclosure. Such regulation may be achieved through “passive” climate regulator devices that present physical and/or chemical properties that provide regulatory capabilities, such as heatsinks comprising conductive metals in physical contact with a device that diffuse excess heat over a wide surface area to facilitate cooling, and screens that trap particulate matter to reduce contamination within the enclosure. Further climate regulation may be provided by “active” climate regulator devices that utilize electric power. For example, the temperature of the air within the enclosure may be regulated by fans, air conditioners, and heaters; humidity regulation may be regulated by humidifiers and dehumidifiers; air pressure may be regulated by compressors; and particulate matter may be regulated by electrostatic air filters. Additionally, the airflow within the chassis may be directed by a plenum, comprising, e.g., an inlet configured to draw air into the plenum; a physical channel positioned and configured to guide the airflow through the chassis and past the devices stored therein; and an exhaust where the airflow past the devices may exit the chassis, thus expelling heat, humidity, particulate contaminants, or other climate properties that have been removed from the enclosure and/or the devices stored therein.

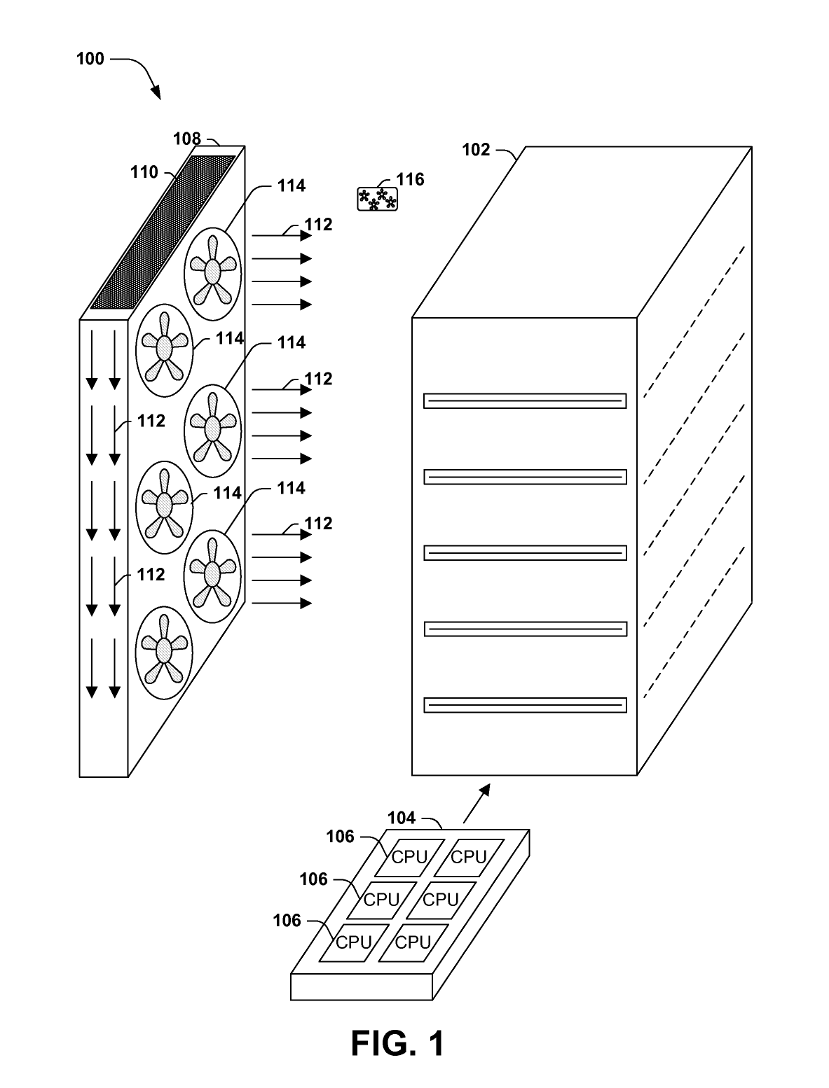

FIG. 1 presents an illustration of an exemplary scenario 100 featuring an enclosure 102 of a computer 104 comprising a set of devices 106 (e.g., processors of a computer). The climate within the enclosure 102 may fluctuate in various respects, including the air temperature within the enclosure 102, in part due to heat generated by the operation of the devices 106. In order to regulate air temperature, the enclosure 102 may include a plenum 108 configured to initiate an airflow 112 and to direct the airflow 112 past the devices 106 of the computer 104. The plenum 108 may comprise an inlet 110 configured to admit an airflow 112 into the enclosure 102 and a set of climate regulator devices 114 positioned within the airflow 112 to regulate at least one climate property of the airflow (e.g., the temperature, humidity, barometric pressure, airflow rate, and/or particulate contaminants of the airflow 112), thus providing a climate regulatory effect (e.g., a cooling 116 of the devices 106 within the enclosure 102) to the enclosure 102 and the devices 106 contained therein.

However, the exemplary scenario 100 of FIG. 1 may also reveal some deficiencies in the design of the enclosure 102, and in particular the plenum 108. As a first example, the plenum 108 comprises a distinct unit to service a first enclosure 102, and if a second enclosure 102 is positioned nearby, the cooling 116 provided by the plenum 108 and climate regulator devices 114 is likely isolated to the contents of the first enclosure 102. This isolation may represent various inefficiencies due to the lack of capacity for sharing the airflow 112 and climate regulation among two or more enclosures 102. As a first example, if operating in an isolated manner, the climate regulator devices 114 of respective portions of the enclosure 102 may generate a distinct airflow 112; however, if one set of climate regulator devices 114 fails, the enclosure 102 may not enable the airflow 112 generated by the other set of climate regulator devices to be shared with the portion of the enclosure 102 serviced by the failed set of climate regulator devices 114. As another example, if distinct sets of climate regulator devices 114 are provided that do not intercommunicate, the climate regulator devices 114 may operate in a conflicting manner, e.g., by endeavoring to achieve different target air temperatures within the enclosure 102. These and other disadvantages may arise from design choices for the architecture of the enclosure 102.

B. Presented Techniques

Presented herein are techniques for architectural designs of an enclosure 102 that improve the efficiency and effectiveness of climate regulation. The enclosure 102 may store a set of one or more chassis, each separately mountable at a position within the enclosure 102 and storing a subset of devices 106. For each chassis, the enclosure 102 comprises a plenum 108 and a set of climate regulator devices 114 that together generate a climate-regulated airflow directed at the devices 106 of the chassis. In accordance with these techniques, when two or more chassis are mounted adjacently within the enclosure 102, the plena may be connected to form a joint plenum presenting a single airflow, generated and regulated by the climate regulator devices 114 of both chassis, that regulates the climate of the devices 106 within both chassis. Moreover, if additional chassis are adjacently mounted within the enclosure 102, the unified plenum 108 may extend to unify the airflow 112 among the plena 108 of three or more chassis, thus creating additional efficiency and effectiveness in the generation and climate regulating effects of the airflow 112.

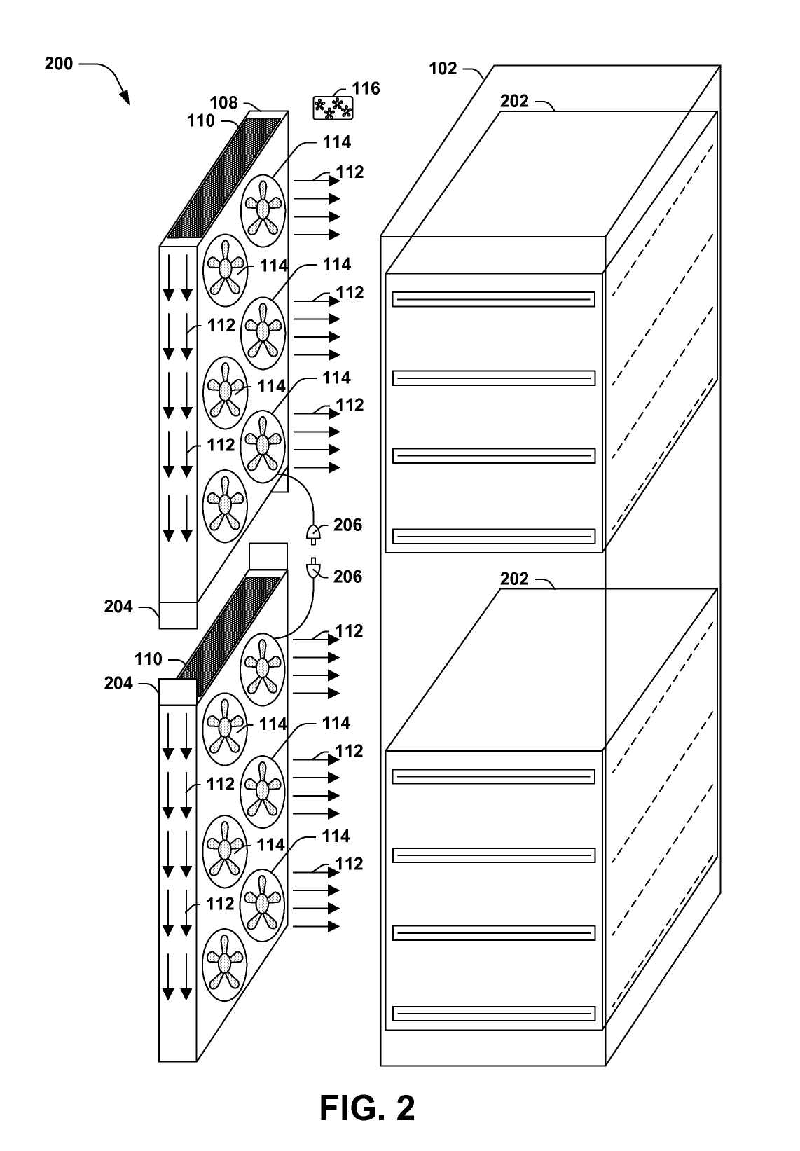

FIG. 2 presents an illustration of an exemplary scenario 200 featuring an architecture of an enclosure 102 designed according to the techniques presented herein. In this exemplary scenario 200, the enclosure 102 comprises a set of chassis 202, each mountable at a position within the enclosure 102 and storing a set of devices 106. A plenum 108 is provided for each chassis 202 (e.g., either physically integrated with the chassis 202, physically integrated with the enclosure 102 and coupling with a mounted chassis 202, or as a separately mountable component of the enclosure 102) that generates an airflow 112 from an inlet 110, past a set of climate regulator devices 114, and toward the devices 106 stored within the chassis 202. Moreover, each plenum 108 may comprise a set of plenum connectors 204, and when two chassis 202 are adjacently mounted (e.g., physically touching or in close physical proximity), the plenum connectors 204 may couple to connect the plena 108 into a single, joint plenum 108 generating a single climate-regulated airflow 112 that is directed at the devices 106 stored within both chassis 202. Thus, rather than each plenum 108 generating a separate airflow 112 using an isolated set of climate regulator devices 114, the plena 108 may form a unified air passage with a single airflow 112 regulated by the climate regulator devices 114 of both plena 108. The climate regulator devices 114 may also be customized for the techniques presented herein; e.g., the climate regulator devices 114 of each plenum 108 may include a climate regulator connector 206, and the climate regulator connectors 206 of adjacent chassis 202 may be connected to form a single, intercommunicating set of climate regulator devices 114 of the unified plenum 108 shared by both chassis 202. For example, the climate regulator connector 206 may enable the climate regulator devices 114 to share power from a single power source; to share information about the regulation of climate within the chassis 202; and/or to coordinate operating information, such as the selection of a climate regulator setting that may enable the climate regulator devices 114 serving both chassis 202 to reach a climate regulation target (e.g., a target temperature within the enclosure 102). These and other advantages may be achievable through the architectures presented herein.

C. Variations

The architecture presented herein for the chassis 202, plena 108, and climate regulator devices 112 may be implemented with variations in many aspects, and some variations may present additional advantages and/or reduce disadvantages with respect to other variations of these and other architectures and implementations. Moreover, some variations may be implemented in combination, and some combinations may feature additional advantages and/or reduced disadvantages through synergistic cooperation.

C1. Scenarios

A first aspect that may vary among embodiments of these techniques relates to the scenarios wherein such techniques may be utilized.

As a first variation of this first aspect, the techniques presented herein may be used to regulate climate within many types of enclosures 102 storing many types of devices 106. For example, the enclosures 102 may comprise a chassis and case of a workstation; the exterior of a notebook or palmtop computer; a cabinet of a server; or a rack storing a set of servers or workstation computers operating with various degrees of independence (e.g., a set of exposed mainboards with processing units comprising the blades of a multi-blade server, or a set of fully autonomous workstations that may communicate in a server/client or peer-to-peer manner or may be fully isolated from one another). Additionally, climate regulation may be provided on behalf of many types of devices 106 stored within the enclosure 102, such as microprocessors; volatile memory circuits; nonvolatile storage devices such as hard disk drives and solid-state storage devices; input/output devices, such as display adapters, sound renderers, video and audio devices, and media encoding and decoding circuits; communications components, such as network adapters, switches, hubs, routers, modems, transceivers, and repeaters; and infrastructure components, such as mainboards and buses.

As a second variation of this first aspect, many types of climate regulation may be provided by many types of climate regulator devices 114 (e.g., by the actual climate regulating component within the climate regulator device 114). As a first such example, the air temperature within the enclosure 102 may be regulated by climate temperature regulating components, such as heaters and evaporative- or coolant-driven air conditioners. As a second such example, humidity within the enclosure 102 may be regulated by climate humidity regulating components, such as humidifiers and dehumidifiers. As a third such example, air pressure within the enclosure 102 may be regulated by climate air pressure regulating components, such as compressors configured to direct air into or out of the enclosure 102. As a fourth such example, airflow rate may be regulated by climate airflow regulating components, such as fans and adjustable windscreens. As a fifth such example, airborne particulate content within the enclosure 102 may be regulated by climate particulate content regulating components, such as electrostatic air filters. These and other scenarios may advantageously utilize the techniques presented herein.

C2. Plenum Design

A second aspect that may vary among embodiments of these techniques relates to the manner of measuring the inlet climate property of air directed into the enclosure 124.

As a first variation of this second aspect, the plena 108 of adjacently mounted chassis 202 may be connected to create a joint plenum in various ways. As a first such example, the plenum connectors 204 of respective chassis 202 may comprise a plenum port, such as an aperture in a chassis wall of the chassis 202 that is covered by a plenum port cover when the chassis 202 is not mounted adjacent to another chassis 202. When the chassis 202 is mounted adjacent to another chassis, the plenum port covers may be removed to expose and align the plenum ports in the chassis walls of the adjacent chassis 202, thus creating a communicating air passage through which the airflows 112 of the separate plena 108 are united into a joint plenum.

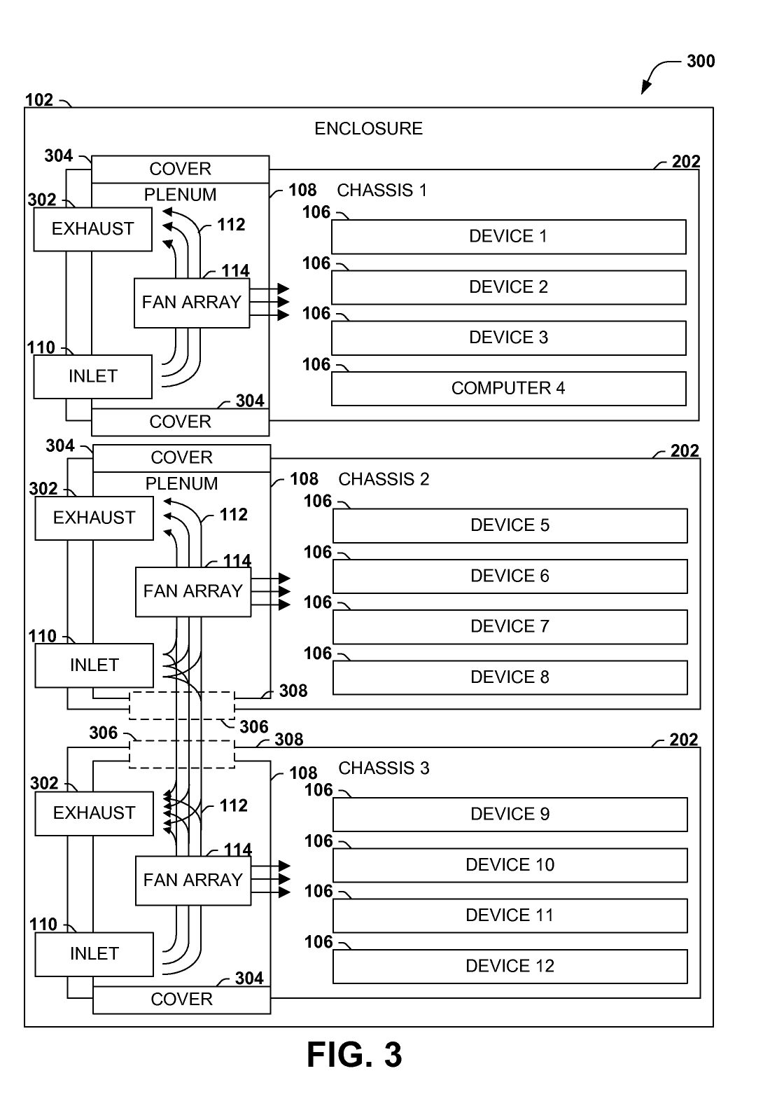

FIG. 3 presents an illustration of an exemplary scenario 300 featuring an example of this first variation of this second aspect. In this exemplary scenario 300, an enclosure 102 comprises a set of three adjacently mounted chassis 202, each comprising a set of devices 106 and a plenum 108 through which an airflow 112 may be generated, climate-regulated by a climate regulator device 114 (e.g., a fan array), and directed at the devices 106. In particular, the plenum 108 of each chassis 202 may comprise an inlet 110 configured to initiate the airflow 112 within the plenum 108 and the chassis 202; an exhaust 302 configured to release the airflow 112 from the plenum 108 and the chassis 202; and at least one plenum port 306 in a plenum wall 308 of the chassis 202 that is ordinarily covered by a removable plenum port cover 304. Although adjacently mounted, the first chassis 202 is isolated from the second chassis 202 by the plenum port covers 304, and each chassis 202 may generate and utilize a separate airflow 112 for the devices 106 stored therein. However, the plenum port covers 304 between the second chassis 202 and the third chassis 202 have been removed, thus creating a coupled pair of plenum ports 306 that form a communicating air passage. This air passage enables the second chassis 202 and the third chassis 202 to form a joint plenum that combines the airflow 112 generated by the climate regulator devices 114 of each chassis 202 into a single, shared airflow 112 that serves the devices 106 within both chassis 202. In this manner, the plenum port 306 and plenum port cover 304 of each chassis 202 provides a plenum connector that enables the formation of a joint plenum among two or more chassis 202.

As a second example of this first variation of this second aspect, a chassis 202 may be designed to utilize an inlet 110 and an exhaust 302 as plenum connectors. For example, the inlet 110 and exhaust 302 may be aligned such that when two chassis 202 are mounted in close proximity, the exhaust 302 of one chassis 202 is aligned with the inlet 110 of the adjacent chassis 202, thus forming a communicating air passage that joins the airflows 112.

As a second variation of this second aspect, the enclosure 102 may be designed to provide access to the plenum 108 and climate regulator devices 108. In many enclosures 102, the plenum 108 is positioned at the back, side, or bottom of the enclosure 102. In order to examine the plenum 108 or maintain or upgrade the climate regulator devices 114, the user may have to reach past or under the devices 106 (possibly while the devices 106 are operational), and/or may have to remove some of the devices 106 from the enclosure 102 (likely while disabling the devices 106, resulting in downtime). In order to alleviate this difficulty, the plenum 108 may comprise an exterior plenum surface featuring a detachable plenum portion that, when detached, enables a user to access the plenum 108. Moreover, the climate regulator devices 114 may be mounted on the detachable plenum portion, such that when the detachable plenum portion is detached and removed from the chassis, the climate regulator devices 114 are together removed from the chassis and are thus user-serviceable. These architectural features may provide access to the plenum 108 and the climate regulator devices 114 without removing or manually circumventing the devices 106 within the chassis.

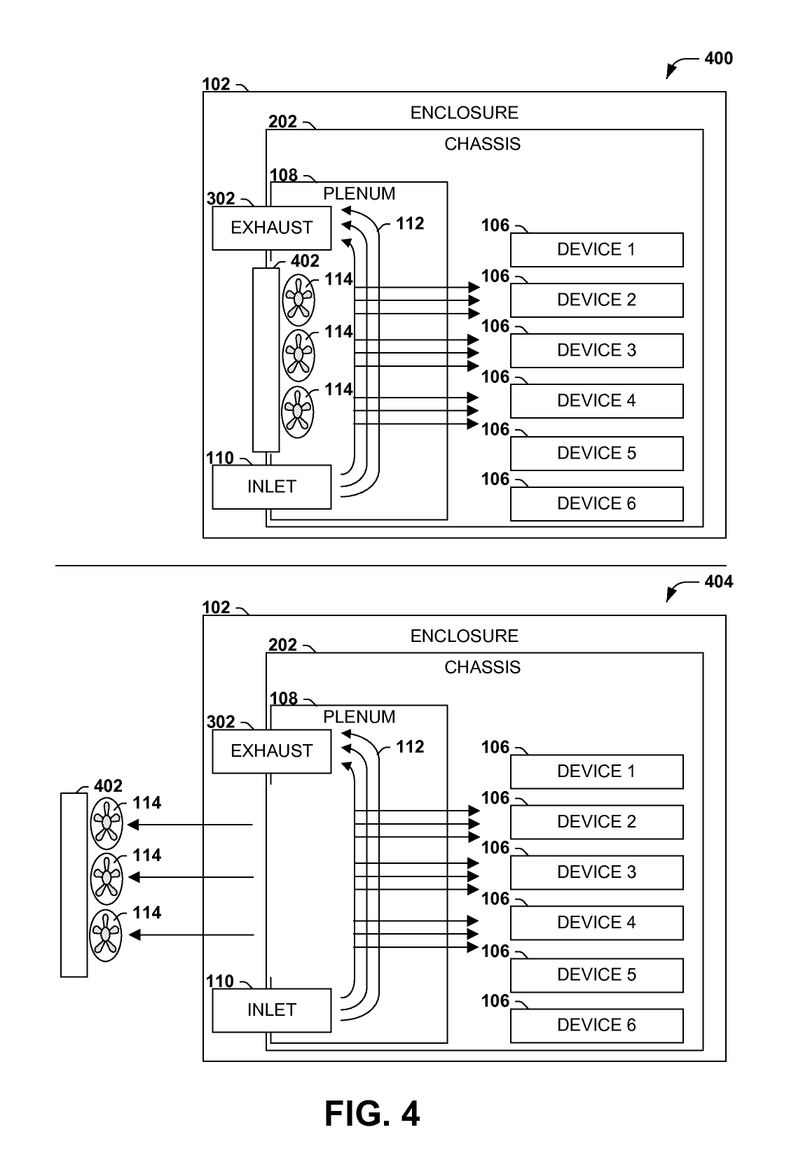

FIG. 4 presents an illustration of an exemplary scenario featuring this second variation of this second aspect. In this exemplary scenario, at a first time point 400, an enclosure 102 is provided wherein a chassis 202 storing a set of devices 106 may be mounted, wherein the chassis 202 comprises a plenum 108 storing a set of climate regulator devices 114 and configured to direct a climate-regulated airflow 112 toward the devices 106. In accordance with this second variation of this second aspect, at a second time point 404, the plenum 108 comprises a detachable plenum portion 402, wherein an exterior plenum surface of the plenum 108 (e.g., an exterior portion of the chassis 202 comprising a side wall of the plenum 108) may be detached by a user from outside of the chassis 202, thus providing exterior access to the plenum 108 that is not blocked by the devices 106. Additionally, the climate regulator devices 114 may be mounted within the plenum 108 on the detachable plenum portion 402, such that detachment and removal of the detachable plenum portion 402 also withdraws the climate regulator devices 114 from the plenum 108, thus providing maintenance access to the climate regulator devices 114 that is not obstructed by the devices 106. Those of ordinary skill in the art may devise many such variations in the architecture of the plenum 108 that may improve the efficiency and accessibility thereof in accordance with the techniques presented herein.

C3. Climate Regulator Design

A third aspect that may vary among embodiments of these techniques relates to the climate regulator devices 114 included in the plenum 108.

As a first variation of this third aspect, the plena 108 of respective chassis 202 may provide a variable number of climate regulator devices 114, based on various considerations. As a first such example, the plenum 108 may include one climate regulator device 114 that is capable of servicing all of the devices 106; one or more climate regulator devices 114 per device 106 stored in the chassis 202; or an intermediate number of climate regulator devices 114. Moreover, a climate regulator device set may include a homogeneous set of climate regulator devices 114, or may include climate regulator devices 114 with different operating characteristics (e.g., a high-powered fan configured to generate a high airflow rate when temperatures are high, and a low-powered fan configured to generate a low airflow rate when temperatures are acceptable).

As a second variation of this third aspect, the chassis 202 may be configured to utilize all provided climate regulator devices 114 at all times, or may utilize a variable number of climate regulator devices 114 depending on various circumstances. As a first such example, the chassis 202 may alter the utilized number of climate regulator devices 114 based on demand for climate regulation within the chassis 202; e.g., more climate regulator devices may be utilized if high air temperature is detected within the chassis 202. As a second such example, the chassis 202 may alter the utilized number of climate regulator devices 114 based on the number of devices 106 stored and utilized in the chassis 202. This variation may provide an adequate number of climate regulator devices 114 to serve a fully loaded chassis 202, and may also conserve power by utilizing a lower number of climate regulator devices 114 when the chassis 202 is not fully loaded with devices 106. As a third example, the number of climate regulator components 114 in the plenum 108 may outnumber the devices 106 stored in the chassis 202 to enable fault tolerance in the event of a failure of one or more climate regulator devices 114.

As a third variation of this third aspect, respective climate regulator devices 114 may be configurable to operate at one of several climate regulator settings. For example, a fan may operate at variable fan speeds; a fan array may utilize a variable number of fans; and a heater may operate at different levels to generate different amounts of heat. The climate regulator setting of a climate regulator device 114 may be manually selectable by a user (e.g., a hardware switch provided on the climate regulator device 114), or may be controlled by a climate regulator controller provided in the chassis 202 that is configured to select a climate regulator setting for the climate regulator device 114 based on various conditions. As a first such example, a climate regulator controller may select a climate regulator setting in view of a connection of the plenum connector 204 of the plenum 108 of the chassis 202 with a plenum connector 204 of a plenum 108 of an adjacent chassis 202, and/or a connection of the climate regulator connector 206 of the climate regulator device 114 with the climate regulator connector 206 of a climate regulator device 114 of an adjacent chassis 202 (e.g., whether the climate regulator devices 114 are only responsible for providing airflow 112 to the devices 106 of the chassis 202, or are interoperating with the climate regulator devices 114 of other chassis 202 in order to cool the devices 106 in several chassis 202). As a second such example, a climate regulator controller may select a climate regulator setting in view of the number and types of devices 106 in the chassis 202 (e.g., the high or low operating priority of the devices 106, and/or the climate tolerance ranges of the devices 106). As a third such example, a climate regulator controller may select a climate regulator setting in view of the number and types of climate regulator devices 106 in the chassis 202 (e.g., selecting a higher-powered climate regulator setting if fewer climate regulator devices 114 are present or operational). These considerations may also include the numbers and types of devices 106 and/or climate regulator devices 114 stored in an adjacent chassis 202 that is served by a joint plenum.

As a fourth example of this third variation of this third aspect, a climate regulator controller may select a climate regulator setting in view of a climate property measured for the airflow 112 directed at the devices 106. For example, the chassis 202 or plenum 108 may also include a climate detector that measures one or more climate properties of the airflow 112 (e.g., the temperature, humidity, or rate of the airflow 112), and the climate regulator devices 114 may be adjusted according to the measurement, thus providing a feedback mechanism to tune the climate regulator devices 114 for the current conditions inside the chassis 202. In particular, the climate regulator selector may perform the selection in order to achieve a target airflow, such as a target temperature or a target airflow rate of the airflow 112 directed at the devices 106 within the chassis 202. Moreover, different target airflows may be selected based on whether the chassis 202 is or is not connected to an adjacent chassis 202; e.g., a first target airflow may be selected if the airflow 112 of the plenum 108 is only directed at the devices 106 of the same chassis 202, and a second target airflow may be selected if the airflow 112 of a joint plenum is directed at the devices 106 of two or more chassis 202.

As a fifth variation of this third aspect, the enclosure 102 may comprise or be operably coupled with a chassis management component that is configured to monitor and log a broad range of conditions of the chassis 202 and/or the enclosure 102 in order to achieve holistic regulation of the devices 106 and the enclosure 102. The climate regulator devices 114 may interoperate with the chassis management component by reporting various operations to the enclosure management component, and/or by using a selected climate regulator setting identified by the chassis management component.

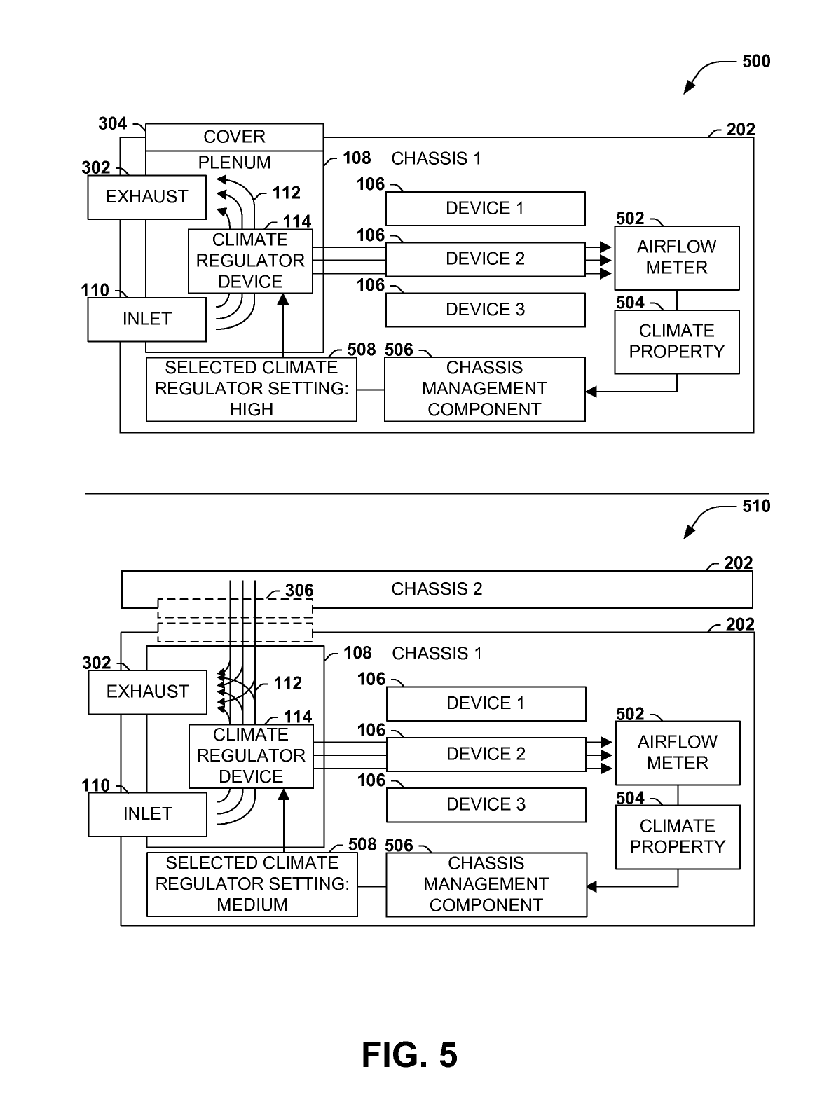

FIG. 5 presents an illustration of an exemplary scenario featuring an embodiment incorporating several of the variations of respective aspects presented herein. In this exemplary scenario, an enclosure 102 is configured to store and operate a set of devices 106. In order to regulate the climate within the enclosure 102, a chassis management component 506 may be provided that is operably coupled with an airflow meter 502 to detect various climate properties 504 of the airflow 112 directed at the devices 106. Moreover, the chassis management component 506 may provide instructions to the climate regulator devices 114, including the selection of a selected climate regulator setting 508 to be applied by the climate regulator device 114 in order to adjust the climate regulation of the airflow 112. For example, at a first time point 500, the chassis 202 is operating in isolation, and the climate management component 506 may instruct the climate regulator device 114 to use a high climate regulator setting 508 in order to achieve adequate climate regulation of the devices 106 stored in the chassis 202. However, at a second time point 510, the chassis 202 may be connected with an adjacent chassis 202 in the enclosure 102 to generate a joint plenum, such that the airflow 112 generated and regulated by the climate regulator devices 114 of the two adjacent chassis 202 may be more powerful and efficient than that created by one chassis 202 in isolation. Therefore, the chassis management component 506 may identify the operation of the climate regulator devices 114 in the joint plenum, and may instruct the climate regulator devices 114 to use a lower selected climate regulator setting 508 in order to conserve energy. In this manner, the chassis management component 506 operates the climate regulator devices 114 in order to achieve climate regulation within the enclosure 102 according to several of the variations of the techniques presented herein. Those of ordinary skill in the art may devise many such variations while implementing the techniques presented herein.

E. Computing Environment

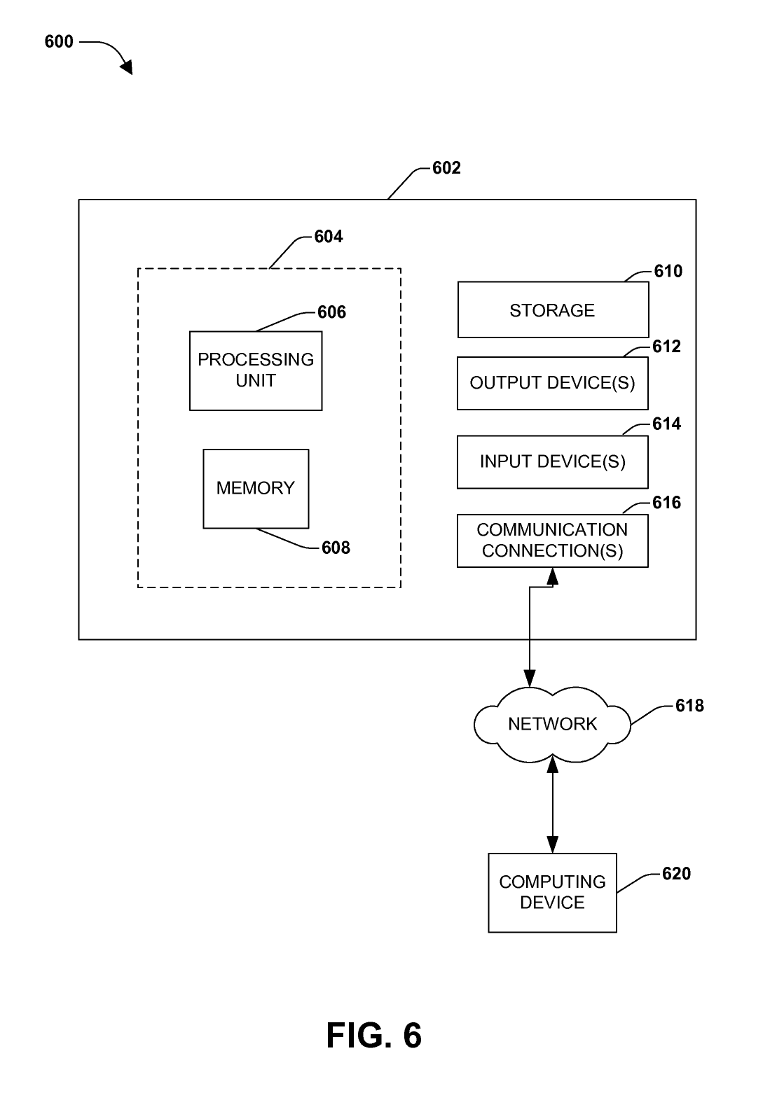

FIG. 6 presents an illustration of an exemplary computing environment within a computing device 602 wherein the techniques presented herein may be implemented. Example computing devices include, but are not limited to, personal computers, server computers, hand-held or laptop devices, mobile devices (such as mobile phones, Personal Digital Assistants (PDAs), media players, and the like), multiprocessor systems, consumer electronics, mini computers, mainframe computers, and distributed computing environments that include any of the above systems or devices.

FIG. 6 illustrates an example of a system 600 comprising a computing device 602 configured to implement one or more embodiments provided herein. In one configuration, the computing device 602 includes at least one processor 606 and at least one memory component 608. Depending on the exact configuration and type of computing device, the memory component 608 may be volatile (such as RAM, for example), non-volatile (such as ROM, flash memory, etc., for example) or an intermediate or hybrid type of memory component. This configuration is illustrated in FIG. 6 by dashed line 604.

In some embodiments, device 602 may include additional features and/or functionality. For example, device 602 may include one or more additional storage components 610, including, but not limited to, a hard disk drive, a solid-state storage device, and/or other removable or non-removable magnetic or optical media. In one embodiment, computer-readable and processor-executable instructions implementing one or more embodiments provided herein are stored in the storage component 610. The storage component 610 may also store other data objects, such as components of an operating system, executable binaries comprising one or more applications, programming libraries (e.g., application programming interfaces (APIs), media objects, and documentation. The computer-readable instructions may be loaded in the memory component 608 for execution by the processor 606.

The computing device 602 may also include one or more communication components 616 that allows the computing device 602 to communicate with other devices. The one or more communication components 616 may comprise (e.g.) a modem, a Network Interface Card (NIC), a radiofrequency transmitter/receiver, an infrared port, and a universal serial bus (USB) USB connection. Such communication components 616 may comprise a wired connection (connecting to a network through a physical cord, cable, or wire) or a wireless connection (communicating wirelessly with a networking device, such as through visible light, infrared, or one or more radiofrequencies.

The computing device 602 may include one or more input components 614, such as keyboard, mouse, pen, voice input device, touch input device, infrared cameras, or video input devices, and/or one or more output components 612, such as one or more displays, speakers, and printers. The input components 614 and/or output components 612 may be connected to the computing device 602 via a wired connection, a wireless connection, or any combination thereof. In one embodiment, an input component 614 or an output component 612 from another computing device may be used as input components 614 and/or output components 612 for the computing device 602.

The components of the computing device 602 may be connected by various interconnects, such as a bus. Such interconnects may include a Peripheral Component Interconnect (PCI), such as PCI Express, a Universal Serial Bus (USB), firewire (IEEE 794), an optical bus structure, and the like. In another embodiment, components of the computing device 602 may be interconnected by a network. For example, the memory component 608 may be comprised of multiple physical memory units located in different physical locations interconnected by a network.

Those skilled in the art will realize that storage devices utilized to store computer readable instructions may be distributed across a network. For example, a computing device 620 accessible via a network 618 may store computer readable instructions to implement one or more embodiments provided herein. The computing device 602 may access the computing device 620 and download a part or all of the computer readable instructions for execution. Alternatively, the computing device 602 may download pieces of the computer readable instructions, as needed, or some instructions may be executed at the computing device 602 and some at computing device 620.

F. Usage of Terms

As used in this application, the terms “component,” “module,” “system”, “interface”, and the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Furthermore, the claimed subject matter may be implemented as a method, apparatus, or article of manufacture using standard programming and/or engineering techniques to produce software, firmware, hardware, or any combination thereof to control a computer to implement the disclosed subject matter. The term “article of manufacture” as used herein is intended to encompass a computer program accessible from any computer-readable device, carrier, or media. Of course, those skilled in the art will recognize many modifications may be made to this configuration without departing from the scope or spirit of the claimed subject matter.

Various operations of embodiments are provided herein. In one embodiment, one or more of the operations described may constitute computer readable instructions stored on one or more computer readable media, which if executed by a computing device, will cause the computing device to perform the operations described. The order in which some or all of the operations are described should not be construed as to imply that these operations are necessarily order dependent. Alternative ordering will be appreciated by one skilled in the art having the benefit of this description. Further, it will be understood that not all operations are necessarily present in each embodiment provided herein.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or more” unless specified otherwise or clear from context to be directed to a singular form.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

What is claimed is:

1. A chassis of an enclosure configured to store at least one device, the chassis comprising:
at least one climate regulator device configured to regulate a climate of an airflow within the chassis;
a plenum configured to direct the airflow at the devices; and
a plenum connector configured to connect with a plenum connector of an adjacent chassis in the enclosure to form a joint plenum combining the airflows of the chassis.

2. The chassis of claim 1:
the plenum connector comprising a plenum port in a chassis wall of the chassis; and
the plenum comprising a plenum port cover configured to cover the plenum port when the plenum connector is not coupled with a plenum connector of an adjacent chassis.

3. The chassis of claim 1:
the plenum connector of the chassis comprising an exhaust of the chassis configured to release the airflow from the enclosure; and
the plenum connector of the adjacent chassis comprising an inlet of the chassis configured to initiate the airflow in the enclosure.

4. The chassis of claim 1, the plenum comprising an exterior plenum surface featuring a detachable plenum portion configured to detach from the chassis to enable access to the plenum.

5. The chassis of claim 4, the climate regulator devices mounted on the detachable plenum portion.

6. The chassis of claim 1, the climate regulator devices of the chassis outnumbering the devices stored in the chassis.

7. The chassis of claim 1:
respective climate regulator devices comprising at least two climate regulator settings; and
the chassis comprising a climate regulator controller configured to, for respective climate regulator devices, select a selected climate regulator setting.

8. The chassis of claim 7, the climate regulator controller configured to select the selected climate regulator setting in view of a connection of the plenum connector with a plenum connector of an adjacent chassis.

9. The chassis of claim 7, the climate regulator controller configured to select the selected climate regulator setting in view of the devices in the chassis.

10. The chassis of claim 7, the climate regulator controller configured to select the selected climate regulator setting in view of the climate regulator devices in the chassis.

11. The chassis of claim 10, the climate regulator controller configured to select the selected climate regulator setting in view of the climate regulator devices in an adjacent chassis having a plenum connected to the plenum of the chassis.

12. The chassis of claim 7, comprising: a climate detector configured to measure a climate property of the airflow directed at the devices.

13. The chassis of claim 12, the climate regulator controller configured to select the selected climate regulator setting in view of the climate property detected by the climate detector.

14. The chassis of claim 1, the chassis comprising a chassis management component configured to communicate with the climate regulators.

15. The chassis of claim 14, the chassis management component configured to detect a connection of the plenum of the chassis with a plenum of an adjacent chassis.

16. A climate regulator device usable with an enclosure comprising at least one chassis respectively storing at least one device, the climate regulator comprising:
a climate regulating component configured to regulate airflow within the chassis directed at the devices by a plenum; and
a climate regulator connector configured to, when the plenum of the chassis is connected with a plenum of an adjacent chassis to from a joint plenum combining the airflows of the chassis, connect to a climate regulator connector of a climate regulator of the adjacent chassis.

17. The climate regulator device of claim 16, the climate regulating component selected from a climate regulating component set comprising:
a climate temperature regulating component;
a climate humidity regulating component;
a climate air pressure regulating component;
a climate airflow regulating component; and
a climate particulate content regulating component.

18. The climate regulator device of claim 16:
the climate regulating component operable at at least two climate regulator settings; and
the climate regulator connector configured to communicate with at least one climate regulator device of the adjacent chassis to communicate a selected climate regulator setting of the climate regulating component.

19. The climate regulator device of claim 18:
the climate regulator setting selected to:
when the plenum of the chassis is not connected to a plenum of an adjacent chassis, achieve a target airflow directed at the devices of the chassis; and
when the plenum of the chassis is connected to a plenum of an adjacent chassis, achieve a target airflow directed at the devices of the chassis and the adjacent chassis.

20. A chassis of an enclosure configured to store at least one device, the chassis comprising:
a plenum configured to direct an airflow at the device of the chassis, the plenum comprising:
a plenum connector comprising a plenum port in a chassis wall of the chassis configured to, when coupled with a plenum port of an adjacent chassis in the enclosure, form a joint plenum combining the airflows of the chassis;
a plenum port cover configured to cover the plenum port when the plenum connector is not coupled with a plenum connector of an adjacent chassis; and
an exterior plenum surface comprising a detachable plenum portion configured to detach from the plenum surface to enable access to the plenum;
at least two climate regulator devices mounted on the detachable plenum portion and configured to regulate a climate of an airflow within the chassis, the climate regulator devices of the chassis outnumbering the devices stored in the chassis, respective climate regulator devices comprising:
a climate regulating component operable at at least two climate regulation settings to regulate airflow within the chassis directed at the devices by a plenum; and
a climate regulator connector configured to connect to a climate regulator connector of a climate regulator of the adjacent chassis;
a climate detector configured to measure a climate property of the airflow directed at the devices;
a climate regulator controller configured to, for respective climate regulator devices, select a selected climate regulator setting in view of:
a connection of the plenum connector with a plenum connector of an adjacent chassis;
the device in the chassis and the adjacent chassis;
the climate regulator devices in the chassis and the adjacent chassis; and
the climate property detected by the climate detector;
a chassis management component configured to:
communicate with the climate regulators, and
a connection of the plenum of the chassis with a plenum of an adjacent chassis.
